(19) United States
(12) Patent Application Publication
(10) Pub. No.: US 2014/0216807 A1
(43) Pub. Date: Aug. 7, 2014

(54) ELECTROMAGNETIC SHIELDING GASKET AND MANUFACTURE METHOD THEREOF

(71) Applicant: 3M INNOVATIVE PROPERTIES COMPANY, St. Paul, MN (US)

(72) Inventors: Weide Liu, Shanghai (CN); Jing Fang, Shanghai (CN)

(73) Assignee: 3M INNOVATIVE PROPERTIES COMPANY, St. Paul, MN (US)

(21) Appl. No.: 14/116,932

(22) PCT Filed: May 23, 2011
(86) PCT No.: PCT/CN2011/074517

§ 371 Date: Nov. 11, 2013

(51) Int. Cl. H05K 9/00

(52) U.S. Cl. CPC H05K 9/0088
USPC 174/358; 205/255; 427/123; 427/124

(57) ABSTRACT

The present invention provides an electromagnetic shielding gasket and a method for making the same, wherein good electrical conductivity and magnetic diffusivity are achieved by electroplating a layer of Co/Ni alloy according to an appropriate ratio on an open-cell foam, and the gasket can accomplish shielding function for electrical field and magnetic field at the same time.

### FIELD OF THE INVENTION

The present invention relates to electromagnetic shielding technology, and more specifically, relates to an electromagnetic shielding gasket useful for shielding electromagnetic interference (EMI)/radio frequency interference (RFI). The present invention also relates to a method for making the electromagnetic shielding gasket.

### BACKGROUND OF THE INVENTION

Electromagnetic interference (EMI) is an undesired portion of electromagnetic emission generated in or radiated from an electronic/electric device, and poses disturbance to normal operation of electronic/electric devices. Theoretically, such an electromagnetic interference may occur in any frequency band of electromagnetic spectrum. Radio Frequency Interference (RFI) is often accompanied by Electromagnetic Interference (EMI). Practically, Radio Frequency Interference (RFI) is restricted to the radio frequency band of the electromagnetic frequency spectrum, i.e., the frequency band from 10 KHz to 100 GHz.

In order to effectively prevent electromagnetic interference (EMI)/radio frequency interference (RFI), a shielding element is usually placed between an electromagnetic interference/radio frequency interference source and an area that needs protection. This shielding element is used to prevent electromagnetic energy from radiating from a source of electromagnetic interference/radio frequency interference. Likewise, it can also be used to prevent external electromagnetic energy from entering a source of electromagnetic interference/radio frequency interference.

In general, the shielding element takes the form of an electrically conductive enclosure, which can be grounded, for example, via a grounding wire on a PCB board. In prior art, this electrically conductive enclosure can be integrally formed by an electromagnetic shielding gasket material. Moreover, in engineering practices, due to the needs from aspects of internal electric circuit or structure, a groove may be made on the electrically conductive enclosure; thereby a gap is formed on the shielding element. In such a case, a shielding gasket may be used to fill the gap formed on the shielding element to prevent electromagnetic energy from radiating from a source of electromagnetic interference/radio frequency interference, or prevent external electromagnetic energy from entering electronic/electric devices.

In recent years, electronic/electric devices, such as portable mobile phones, PDA, and navigation systems, become smaller and smaller, and they are required to have good portability. On one hand, in order to prevent dust or moisture from entering the core of these communication devices, for example, the interior of LCD module, and prevent impact and vibration on the modules caused by collision, falling to the ground and the like during personal carrying or shipment, it is necessary to install an absorptive gasket material having high impact and vibration absorption function outside the electronic module used in electronic/electric devices. Usually, such an absorptive gasket material consists of a micro-porous material, such as polyurethane foam, so that the material has certain resilience and recoverability. On the other hand, with the enlargement of screens using LCD module in these electronic communication devices and diversification of functions such as image and text communication and digital photographing, electric circuits and electronic modules used in the electronic/electric devices become very sensitive to static electricity, electromagnetic wave, magnetic field generated from interior and exterior of the devices, and become vulnerable to the influence from internal and external electromagnetic interference/radio frequency interference sources.

For this reason, the absorptive gasket material in the above-described electronic/electric devices is required not only to have high impact and vibration absorption function, but also to have gapless sealing function in narrow spaces inside electronic/electric devices, and to have shielding function against electromagnetic interference (EMI)/radio frequency interference (RFI) generated inside and outside electronic/electric devices.

U.S. Pat. No. 6,309,742 disclosed a shielding gasket that is made by depositing a layer of metal material onto an open-cell foam. Since the deposited metal material can penetrate into the open-cell foam, it provides the open-cell foam with good electrical conductivity. Accordingly, the gasket material can be die-cut into various shapes or be shaped into shielding elements, and can be used to fill in or cover around electronic/electric devices, and then its electrical conductivity can be utilized to shield the electromagnetic interference (EMI)/radio frequency interference (RFI) generated inside and outside electronic/electric device. However, the above-described prior art has some disadvantages and problems. Although the gasket material has a certain level of electrical conductivity and therefore has good shielding performance against static electricity and electrical field, its shielding performance are not satisfactory with regard to the magnetic field generated inside and outside electronic/electric devices, particularly for the near-earth magnetic field.

Thus, there is a need for an electromagnetic shielding gasket that can effectively shield the electrical field and magnetic field at the same time.

### SUMMARY OF THE INVENTION

The objective of the present invention is to provide an electromagnetic shielding gasket that can accomplish shielding function for electrical field and magnetic field at the same time.

According to one aspect of the present invention, there is provided an electromagnetic shielding gasket, comprising a foam substrate and a metal layer deposited on the foam substrate, wherein the metal layer contains nickel and cobalt and the ratio of Co/(Co+Ni) is 0.2% to 85% by weight.

According to another aspect of the present invention, there is provided a method for making electromagnetic shielding gasket, the method comprising the following steps:

performing pre-metalizing treatment to a foam substrate; and

performing metalizing treatment to the pre-metalized foam substrate to obtain a metal layer containing Co and Ni.

The electromagnetic shielding gasket of the present invention can accomplish shielding function for electrical field and magnetic field at the same time.

### BRIEF DESCRIPTION OF THE DRAWINGS

FIG. 1 is a schematic diagram of the structure of the electromagnetic shielding gasket according to one embodiment of the present invention.

FIG. 2 is a schematic diagram of the structure of the electromagnetic shielding gasket according to another embodiment of the present invention.

FIG. 3 is a schematic diagram for the magnetic properties testing method used in the present invention.

FIG. 4 is a SEM photo of the electromagnetic shielding gasket according to one embodiment of the present invention.

FIG. 5 is an EDS spectrum of the electromagnetic shielding gasket according to one embodiment of the present invention.

### DETAILED DESCRIPTION

Unless otherwise specified, all the percentages and ratios described in the present invention are based on weight.

In the electromagnetic shielding gasket of the present invention, the foam substrate is an open-cell foam having cells distributed therein. There are no restrictions to the materials for the foam substrate, as long as they have elasticity and have predetermined recoverability under an external force.

In an embodiment of the present invention, the foam substrate of the electromagnetic shielding gasket is an open-cell foam made from an elastic polymer material or a thermo-elastomer in a foaming process. The elastic polymer material is, for example, polyurethane, polyvinyl chloride, silicone resin, ethylene-vinyl acetate copolymer (EVA), polyethylene and the like.

In an embodiment of the present invention, the foam substrate of the electromagnetic shielding gasket has a thickness of 0.1 to 50 mm, preferably 0.1 to 10 mm, more preferably 0.5 to 5 mm, and the most preferably 1.0 to 3.0 mm. If the thickness is less than 0.1 mm, the form substrate may lose its compressibility and resilience; and if the thickness is more than 50 mm, its electrical conductivity in vertical direction would tend to decrease after metal is deposited on the foam substrate.

On one hand, in order to provide the foam substrate with an ability to absorb impact and block vibration, and meanwhile, in order to ensure a tight seal when the electromagnetic shielding gasket is pressed into a predetermined gap, it is necessary for the foam substrate to have a certain degree of compressibility when an external force is exerted on it. In an embodiment of the present invention, the foam substrate of the electromagnetic shielding gasket has a compressible deformation of 50% or more, preferably 70% or more, more preferably 80% or more, and the most preferably 90% or more, relative to the initial thickness. If the compressible deformation is less than 50% relative to the initial thickness, absorption of high impact and vibration would tend to be inadequate. The compressible deformation as used herein is the value under a pressure of not exceeding 50 PSI.

On the other hand, it is necessary for the foam substrate to have a certain degree of recoverability when the external force is removed from the foam substrate. In an embodiment of the present invention, the foam substrate of the electromagnetic shielding gasket has a residual deformation of 50% or less, preferably 30% or less, more preferably 20% or less, and the most preferably 10% or less. If the residual deformation (permanent deformation) of the foam substrate is more than 50%, its high impact and vibration absorption and gapless sealing functions would tend to decrease after a prolonged use.

In an embodiment of the present invention, the foam substrate of the electromagnetic shielding gasket has a porosity of 10 to 500 ppi, preferably 50 to 300 ppi, more preferably 50 to 200 ppi, and the most preferably 80 to 150 ppi. If the porosity of the foam substrates is lower than 10 ppi, it will be difficult to accomplish metal layer deposition; if the porosity is higher than 500 ppi, mechanical strength of the foam substrate would tend to be inadequate. Vacuum evaporation coating, electroplating or chemical plating and the like may be used to deposit a metal layer containing Co and Ni on the open-cell foam substrate in order for the open-cell foam substrate to possess good electrical conductivity and magnetic diffusivity.

In an embodiment of the present invention, there is provided an electromagnetic shielding gasket, comprising a foam substrate and a metal layer deposited on the foam substrate, and the metal layer contains nickel and cobalt, wherein the ratio of Co/(Co+Ni) is 0.2% to 85% by weight, 2% to 70% by weight in a preferred embodiment, 5% to 50% by weight in a more preferred embodiment, and 5% to 35% by weight in the most preferred embodiment. Since the open-cell foam substrate has many tiny open cells, after a metal layer is deposited on the open-cell foam substrate, the open-cell foam substrate not only obtains surface electrical conductivity, but also obtains free electrical conductivity in the vertical direction and other directions on the open-cell foam substrate, forming a three-dimensional foam structure having good continuous electrical conductivity. Because the metal layer contains Co, ferromagnetism of the electroplated foam is also increased. Cobalt content in Co/Ni alloy is critical for achieving the objectives of the present invention. When the Co/Ni proportion reaches a certain value, its magnetic diffusivity will be significantly increased. In order to achieve good magnetic diffusivity, cobalt content in Co/Ni alloy must be controlled within the above range. In the present invention, the objective is achieved by, for example, controlling the ratio of Co²⁺ and Ni²⁺ ions in electroplating solution. When the weight ratio of Co/(Co+Ni) falls outside of the range, it will be difficult to achieve relatively apparent beneficial results of the magnetic properties while maintaining good electrical conductivity.

In an embodiment of the present invention, the ratio of (Co+Ni)/foam of the foam substrate having nickel and cobalt layer deposited thereon is 1% to 50% by weight, preferably 2% to 30% by weight, more preferably 3% to 20% by weight, and the most preferably 5% to 10% by weight. The metal deposition layer has a thickness of 10 to 2000 nm, preferably 50 to 1800 nm, more preferably 100 to 1500 nm, and the most preferably 200 to 1000 nm. When the weight ratio of (Co+Ni)/foam or the thickness of the metal deposition layer is within the above range, the electromagnetic shielding gasket can provide good shielding function for electrical field and magnetic field, and can have appropriate resilience and recoverability. With the increase of the weight ratio of (Co+Ni)/foam or the thickness of the metal deposition layer, the resilience and recoverability of the electromagnetic shielding gasket decreases.

In an embodiment of the present invention, the metal layer deposited on the foam substrate further comprises a metal selected from molybdenum, manganese, copper, chromium, or a combination thereof. The ratio of total weight of metal to the weight of form in the foam substrate having the metal layer deposited thereon is 1% to 50%, preferably 2% to 40%, more preferably 3% to 30%, the most preferably 5% to 20%. The metal deposition layer has a thickness of 10 to 2000 nm, preferably 50 to 1800 nm, more preferably 100 to 1500 nm, and the most preferably 200 to 1000 nm. When the ratio of total weight of metal to the weight of form or the thickness of the metal deposition layer is within the above range, the electromagnetic shielding gasket can accomplish good shielding function for electrical field and magnetic field, and can have appropriate resilience and recoverability. With the increase of the ratio of total weight of metal to the weight of form or with the increase of the thickness of the metal deposition layer, the resilience and recoverability of the electromagnetic shielding gasket decreases.

In another embodiment of the present invention, a polymer layer, for example a polyurethane layer, is further coated on the metal layer deposited on the foam substrate. The polymer layer mainly has the functions of anti-oxidation and protection of the metal layer.

In an embodiment of the present invention, tensile strength of the electromagnetic shielding gasket is 0.1 to 100 N/in, preferably 0.3 to 80 N/in, more preferably 0.6 to 50 N/in, and the most preferably 1 to 30 N/in. If the tensile strength of the electromagnetic shielding gasket is lower than 0.1 N/in, processing behavior of the electromagnetic shielding gasket would be poor. In the present invention, tensile strength test is performed in accordance with ASTM D 1000 standard, using a standard 1-in wide specimen for testing tensile strength at break.

In an embodiment of the present invention, the surface electric resistance of the electromagnetic shielding gasket is 1 to 2000 mΩ/γ, preferably 5 to 1000 mΩ/γ, more preferably 10 to 800 mΩ/γ, and the most preferably 20 to 500 mΩ/γ. If the surface electric resistance of the electromagnetic shielding gasket is higher than 2000 mΩ/γ, the electromagnetic shielding function of the electromagnetic shielding gasket would tend to be inadequate.

In an embodiment of the present invention, standard ferromagnetic attraction distance of the electromagnetic shielding gasket is more than 1.5 cm, preferably more than 1.8 cm, more preferably more than 2 cm, the most preferably more than 2.5 cm. In the present invention, as the overall magnetic diffusivity of the foam is increased by means of depositing an optimized Co/Ni ferromagnetic coat on the foam substrate, it is not suitable to use conventional test methods of soft magnetic materials for testing this material because the foam substrate is soft and highly compressible. However, since magnetic diffusivity is an important reference parameter for evaluating ferromagnetism of the soft magnetic materials, magnitude of the magnetic diffusivity characterizes magnitude of the effect under the magnetic force of the same magnitude, i.e., intensity of the magnetic lines of force per unit area (density). Usually, the higher the density, the better soft magnetic properties and the stronger exhibited attraction forces. Based on this theory, a standard permanent magnet is used as a constant external magnetic field in the present invention, and the permanent magnet provides constant magnetic forces acting on the metalized (magnetized) foam specimen. In order to characterize magnitude of the magnetic force, a piece of foam of constant weight is used as a load in the present invention to determine magnitude of the attraction force based on the distance at which the effect takes place. It is understandable that, if the foam weight is the same, when the external magnetic field strength (force) is the same, a longer attraction distance means better magnetic diffusivity of the foam specimen and stronger magnetic properties. The electromagnetic shielding gasket of the present invention has longer attraction distance and exhibits better magnetic properties.

In an embodiment of the present invention, compressible deformation of the electromagnetic shielding gasket is more than 30% relative to the initial thickness, preferably more than 50% relative to the initial thickness, more preferably more than 70% relative to the initial thickness, and the most preferably more than 80% relative to the initial thickness. If the compressible deformation is less than 30% relative to the initial thickness, absorption of high impact and vibration would tend to be inadequate.

In an embodiment of the present invention, the residual deformation (permanent deformation) of the electromagnetic shielding gasket is less than 50%, preferably less than 30%, more preferably less than 20%, and the most preferably less than 10%. If the residual deformation (permanent deformation) of the electromagnetic shielding gasket is more than 50%, its high impact and vibration absorption and gapless sealing functions would tend to decrease after a prolonged use.

In addition to the metal-electroplated foam, the electromagnetic shielding gasket of the present invention may also have additional functional layers, such as an electrically conductive layer, release paper, and etc. The additional layers are bonded to the foam by an adhesive. The adhesive may be a conductive adhesive, or a non-conductive adhesive. When a non-conductive adhesive is used, it may have a certain impact on the electrical field shielding performance of the electromagnetic shielding gasket. Preferably, a conductive adhesive is used as the adhesive.

The conductive adhesive may be made by adding an appropriate proportion of conductive particles into an acrylic adhesive. The amount of the conductive particles is such that, for example, the ratio of (conductive particles)/(conductive particles+adhesive) is from 3% to 60% by weight. The conductive particles may be, for example, nickel powder, silver powder, silver-coated glass, silver-coated copper powder, graphite powder (carbon powder), composite conductive particles and the like.

The conductive layer may be various types of metal foil, including copper foil, and it may also be various types of metalized fabrics or nonwoven fabrics, and the like.

The present invention also provides a method for making the electromagnetic shielding gasket, the method comprising the following steps: performing pre-metalizing treatment to a foam substrate; and performing metalizing treatment to the pre-treated foam substrate to obtain a metal layer containing Co and Ni. In the process, the pre-metalizing treatment provides necessary preparation for the subsequent metalizing treatment. It deposits a thin layer of metal Ni on the foam substrate by a vacuum process, or other metals having a similar electric potential such as Pb. The metal layer on foam fabrics is not a continuous layer, and mainly serves as a core for deposition in the subsequent metalizing treatment, for example, as a core for Co²⁺ and Ni²⁺ deposition in aqueous electroplating, to ensure effective deposition of Co²⁺ and Ni²⁺, enabling Co²⁺ and Ni²⁺ ions to migrate simultaneously onto the foam substrate, and to form a substantially uniform, dense and reliable Co/Ni alloy coating. The pre-metalizing treatment may be accomplished, for example, by vacuum evaporation coating, chemical vapor deposition, plasma sputtering and plasma chemical vapor deposition. The metalizing treatment may be accomplished by vacuum evaporation coating, electroplating or chemical plating and the like, for example, by aqueous electroplating.

In order for the electroplated foam to have good ferromagnetic properties, the ratio of Co²⁺ and Ni²⁺ ions in the electroplating solution should be appropriately controlled to ensure that cobalt content in the resulted metal layer is in an appropriate range. In the present invention, the ratio of Co²⁺/(Co²⁺+Ni²⁺) in the electroplating solution is, for example, 0.2% to 85%, preferably 2% to 70%, more preferably 5% to 50%, the most preferably 5% to 35%.

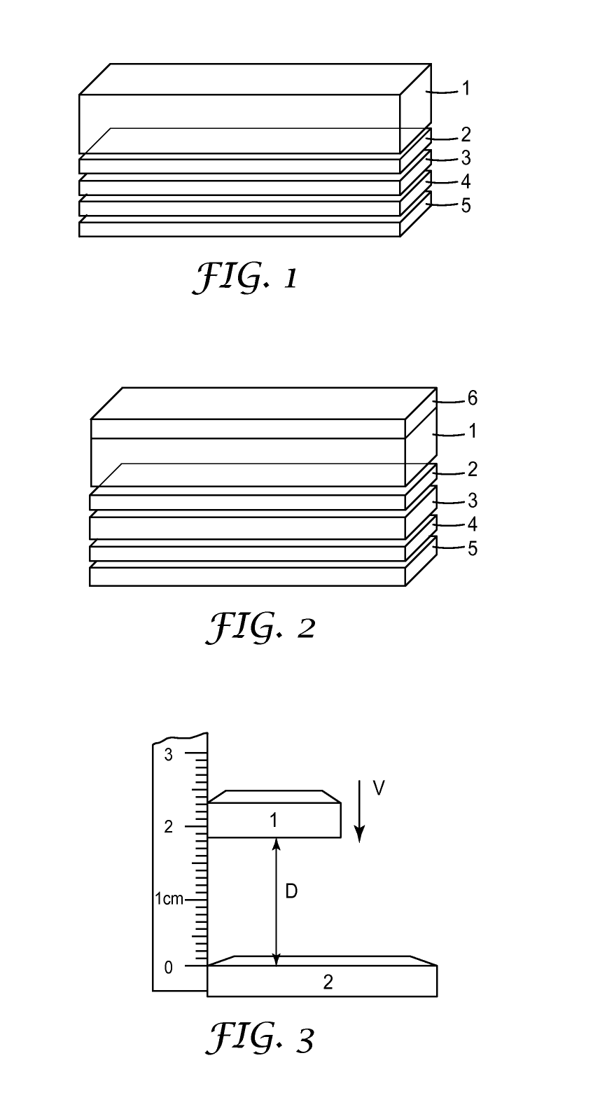

FIG. 1 shows an embodiment of the electromagnetic shielding gasket of the present invention. As shown in FIG. 1, the electromagnetic shielding gasket comprises a cobalt/nickel-electroplated foam 1, a copper foil 3 bonded on one side of the foam by a conductive adhesive 2, and a release paper 5 bonded on the copper foil 3 by a conductive adhesive 4.

FIG. 2 shows another embodiment of the electromagnetic shielding gasket of the present invention. As shown in FIG. 2, the electromagnetic shielding gasket comprises a cobalt/nickel-electroplated foam 1, an electrically conductive layer 6 bonded on one side of the foam, a copper foil 3 bonded on another side of the foam by a conductive adhesive 2, and a release paper 5 bonded on the copper foil 3 by a conductive adhesive 4.

In the present invention, the preparation process for Co/Ni metallization of the open-cell foam includes the steps of:

1. Preparing an open-cell foam with its thickness, width and length meeting the requirement;

2. Performing pre-metalizing treatment (PVD process) to the open-cell foam;

3. Performing Co/Ni aqueous electroplating metalizing treatment to the pre-treated open-cell foam;

4. Drying; and

5. Roll collecting.

### EXAMPLES

The following examples are provided to further illustrate the present invention, but they will not limit the scope of the invention as defined by the appended claims.

I. The Raw Materials Used in the Present Invention and their Origins are Summarized Below.

The polyurethane (PU) foams are purchased from INOAC Corporation, Japan, and their product numbers are summarized in Table 1.

TABLE 1
Properties of the PU foam

| | | | Tensile | Number of | PPI |
|---|---|---|---|---|---|
| Product | | Density | strength | holes | reference |
| name | Color | (Kg/M³) | (KPa) | (holes/25 mm) | value |
| MF-50P3 | white | 28 ± 2 | above 150 | 60 ± 5 | 120-140 |
| MF-50PB | black | 30 ± 3 | above 150 | 55 ± 5 | 110-135 |
| MF-RB | black | 33 ± 4 | above 150 | above 5 | above 110 |
| MF-45RWH | white | 45 ± 3 | above 150 | 60 ± 5 | 120-140 |
| MF-80S | white | 65 ± 5 | above 150 | above 70 | above 150 |

Nickel chloride, nickel sulfate, cobalt sulfate, boric acid and other chemicals used in the examples are industrial grade and purchased from China National Pharmaceutical Group Corporation.

II. Property Characterization Method

1. Test of Residual Deformation

The test was performed according to the following procedure using a high-precision digital thickness gauge (543-392BS, purchased from Mitutoyo Company, Japan) and a stainless steel deformation-retaining clamping fixture that was fixed at four corners by screw nuts.

A 2-in ×2-in foam specimen was cut out and eight evenly distributed points were taken for measuring its freedom thickness (deformation-free thickness), and an average initial thickness T₀ was calculated. When no foam specimen was placed on the deformation-retaining clamping fixture, the screws at the four corners were tightened to make the upper part and lower part tightly fitted, and then the fitted thickness T₁ of the fixture was measured. Then, the foam specimen was placed in the center of the deformation-retaining clamping fixture, and the screws at the four corners were gradually tightened to make the measured thickness T₂ of the fixture to be T₁+(T₀/2), i.e., the foam was pressed and maintained at 50% of the average initial thickness T₀. The clamping fixture with the specimen clamped was placed in a constant temperature oven, and the oven temperature was maintained at 70° C.±2° C. for 22 hours. The clamping fixture was taken out and the screws were loosened, and then the foam specimen was taken out and allowed to cool in a relaxed state for 10 min. Eight evenly distributed points were taken for measuring its freedom thickness (deformation-free thickness), and the average recovered thickness T₃ was calculated. Residual deformation was calculated according to the following formula:

$$X = \frac{{T}_{0} - {T}_{3}}{{T}_{0}} \times 100 \% .$$

2. Test of Surface Electric Resistivity

A standard clamping fixture as specified in MIL-G-83528 standard was used, and the standard weight of the clamping fixture is 250 g. Electrode of the clamping fixture was coated with gold. Contacting area between the electrode and work-piece being measured is 25.4 mm×4.75 mm, and the distance between the electrodes is 25.4 mm. Two electrodes were placed on a surface of an electromagnetic shielding gasket specimen to be measured with the distance between the electrodes being 25.4 mm. The test was complete as soon as the electric resistance between the two electrodes is recorded.

3. Test of Magnetic Properties

The magnetic properties testing method used in the present invention is shown in FIG. 3, wherein 1 represents an NdFeB permanent magnet, 2 represents a Co/Ni electroplating foam specimen, V represents constant speed, D represents the distance at which the foam specimen interacts with the magnetic field generated by the NdFeB permanent magnet. Specific test procedure is as follows: a foam of 5.5-6.0 mg in weight was placed on a flat surface of a wooden desk, and the NdFeB permanent magnet (size: 2.4 cm×1.1 cm×0.3 cm, (BH)ₘₐₓ=25 MGOe, obtained from the Research institute of Functional Materials of Northeast University) was allowed to move downward at a speed of 1 m/min toward the foam, and the distance, by which the foam was moved up due to attraction when the foam interacted with the permanent magnet, was measured.

4. Test of Metal Content and Metal Layer Thickness

In the present invention, the metal content and metal layer thickness were tested using Energy Dispersive Spectroscopy (EDS).

In the EDS test, fabric diameters in the foam and the metal layer thickness could be seen clearly by using an associated scanning electron microscope (SEM).

The instrument is OxFord JSM 6360LV SEM obtained from JEOL, Japan. Its specimen observation area is 20 mm².

### III. Examples

### Example 1

First, pre-treatment PVD vacuum electroplating of PU foam (MF-50P3) was performed under the following conditions:

Vacuum degree: about 0.2 Pa;

Temperature outside the PVD equipment: room temperature;

Target material: metallic pure nickel;

A nickel coating is obtained by belt electroplating (web coating), and the coating is controlled to such an extent that the weight of nickel is less than 5 g per every square meters of foam with a thickness of 1.8 mm.

Then, cobalt, nickel alloy electroplating was performed by using the electroplating solution. Composition of the electroplating solution includes: nickel chloride, nickel sulfate, cobalt sulfate, boric acid, other active additives for electrolytic solution and pure water. For the ratio of the ingredients, see Table 2. The anode used in the electrolytic tank is a nickel plate, and the cathode is the foam pre-treated by PVD per-electroplating. The temperature of the solution in the tank is at room temperature, and working voltage is <12 V. A roll-to-roll type of continuous electroplating process was used with a linear speed of 0.6 m-1.5 m/min.

Then, the belt is dried by hot-air blasting with air temperature being at 60-80 degrees Celsius.

The roll collection speed is the same as the electroplating speed.

The product was characterized using the method as described in section II. The ratio of Co/(Co+Ni) obtained by EDS is 31.0%.

### Examples 2 and 3

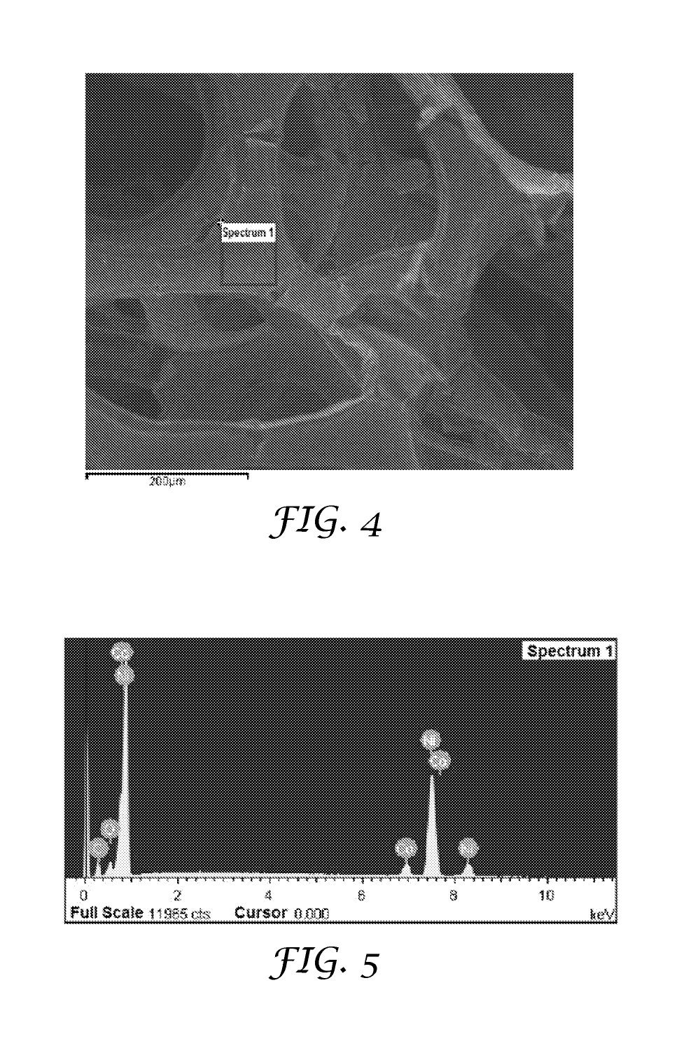

The procedure is substantially the same as in Example 1, except that the electroplating solution having the composition as shown in Table 2 was used. The ratio of Co/(Co+Ni) obtained by EDS in Examples 2 and 3 is 22.4% and 19.9% respectively. FIG. 4 and FIG. 5 are the SEM photo and EDS spectrum for Example 2 respectively.

### Comparative Example 1

Electroplating was performed using an electroplating solution that does not contain cobalt sulfate.

TABLE 2
Composition of the electroplating solution:

| | | | | Comparative |
|---|---|---|---|---|
| | Example 1 | Example 2 | Example 3 | Example 1 |
| NiCl₂ | 230 g | 230 g | 230 g | 230 g |
| CoSO₄ | 300 g | 110 g | 50 g | 0 |
| NiSO₄ | 150 g | 150 g | 150 g | 150 g |
| H₃BO₃ | 50 g | 50 g | 50 g | 50 g |
| Other additives | <2% | <2% | <2% | <2% |
| Distilled water | 1000 mL | 1000 mL | 1000 mL | 1000 mL |

Table 3 shows the test results of compressibility and electrical conductivity of the Examples 1 to 3 and Comparative example 1. It can be seen that, the products of Examples 1 to 3 of the present invention exhibit better compressibility and electrical conductivity.

TABLE 3
Compressibility and electrical conductivity of the products

| | | | | | | | Comparative | |
|---|---|---|---|---|---|---|---|---|
| Test items | Example 1 | | Example 2 | | Example 3 | | Example 1 | |
| Thickness | 1.8 | mm | 1.8 | mm | 1.8 | mm | 1.8 | mm |
| Thickness | 0.25 | mm | 0.25 | mm | 0.25 | mm | 0.45 | mm |
| achievable by | | | | | | | | |
| compression | | | | | | | | |
| Z-axis electric | 2.6 | mΩ/in² | 2.8 | mΩ/in² | 3.0 | mΩ/in² | 16.5 | Ω/in² |
| resistance | | | | | | | | |
| Surface electric | 21 | mΩ/γ | 25 | mΩ/γ | 27 | mΩ/γ | 38 | mΩ/γ |
| resistance | | | | | | | | |

Table 4 shows the data of magnetic properties of Examples 1 to 3 and Comparative example 1 measured according to the method described in section II-3. It can be seen that the attraction distance of Examples 1 to 3 of the present invention is much longer than the attraction distance of Comparative Example 1. As described above, this proves that the products of the present invention possess good magnetic diffusivity.

TABLE 4
Magnetic properties of the products

| Specimen | Attraction distance |
|---|---|
| Example 1 | 3.5 cm |
| Example 2 | 2.9 cm |
| Example 3 | 2.7 cm |
| Comparative example 1 | 1.3 cm |

In summary, the present invention provides an electromagnetic shielding gasket, which possesses good electrical conductivity and magnetic diffusivity, and can accomplish shielding function for electrical field and magnetic field at the same time.

1. An electromagnetic shielding gasket, comprising a foam substrate and a metal layer deposited on the foam substrate, wherein the metal layer contains nickel and cobalt and the ratio of Co/(Co+Ni) is 0.2% to 85% by weight.

2. (canceled)

3. The electromagnetic shielding gasket according to claim 1, wherein the foam substrate has a compressible deformation of 50% or more, relative to the initial thickness.

4. The electromagnetic shielding gasket according to claim 1, wherein the foam substrate has a residual deformation of 50% or less.

5. The electromagnetic shielding gasket according to claim 1, wherein the foam substrate has a porosity of 10 to 500 ppi.

6. The electromagnetic shielding gasket according to claim 1, wherein the foam substrate has a thickness of 0.1 to 50 mm.

7. The electromagnetic shielding gasket according to claim 1, the foam substrate is an open-cell foam made from an elastic polymer material or thermo-elastomer in a foaming process.

8. The electromagnetic shielding gasket according to claim 7, wherein the elastic polymer material is polyurethane, polyvinyl chloride, silicone resin, ethylene-vinyl acetate copolymer (EVA), polyethylene or a mixture thereof.

9. The electromagnetic shielding gasket according to claim 1, wherein the ratio of (Co+NO/foam is 1% to 50% by weight.

10. The electromagnetic shielding gasket according to claim 1, wherein the metal layer has a thickness of 10 to 2000 nm.

11. The electromagnetic shielding gasket according to claim 1, wherein the metal layer deposited on the foam substrate further comprises a metal selected from molybdenum, manganese, copper, chromium, or a combination thereof.

12. The electromagnetic shielding gasket according to claim 11, wherein the ratio of total weight of metal to the weight of form in the foam substrate having the metal layer deposited thereon is 1% to 50%.

13. The electromagnetic shielding gasket according to claim 1, wherein a polymer layer, is further coated on the metal layer deposited on the foam substrate.

14. The electromagnetic shielding gasket according to claim 1, wherein an additional functional layer is adhered to the foam substrate.

15. The electromagnetic shielding gasket according to claim 14, wherein the additional functional layer is an electrically conductive layer or release paper.

16. The electromagnetic shielding gasket according to claim 14, wherein the additional functional layer is adhered to the foam substrate by aconductive adhesive.

17. (canceled)

18. The electromagnetic shielding gasket according to claim 17, wherein the conductive adhesive is an acrylic adhesive having added electrically conductive particles.

19-20. (canceled)

21. The electromagnetic shielding gasket according to claim 15, wherein the electrically conductive layer is a metal foil, or metalized fabrics or nonwoven fabrics.

22. A method for making the electromagnetic shielding gasket according to claim 1, comprising the following steps:
performing pre-metalizing treatment to a foam substrate; and
performing metalizing treatment to the pre-metalized foam substrate to obtain a metal layer containing Co and Ni.

23. The method according to claim 22, wherein the pre-metalizing treatment is accomplished by a vacuum process.

24-25. (canceled)

26. The method according to claim 22, wherein the metalizing treatment is accomplished by vacuum evaporation coating, electroplating or chemical plating.

27-30. (canceled)
